(19) United States
(12) Patent Application Publication
(10) Pub. No.: US 2018/0277559 A1
(43) Pub. Date: Sep. 27, 2018

(54) SEMICONDUCTOR MEMORY DEVICE AND METHOD FOR MANUFACTURING SAME

(71) Applicant: Toshiba Memory Corporation, Minato-ku (JP)

(72) Inventor: Shigeru Kinoshita, Yokohama (JP)

(73) Assignee: Toshiba Memory Corporation, Minato-ku (JP)

(21) Appl. No.: 15/686,474

(22) Filed: Aug. 25, 2017

(30) Foreign Application Priority Data
Mar. 24, 2017 (JP) 2017-059927

(51) Int. Cl. H01L 27/11582; H01L 29/49; H01L 21/28; H01L 29/40; H01L 21/285

(52) U.S. Cl. CPC H01L 27/11582; H01L 29/4966; H01L 21/28282; H01L 27/11565; H01L 21/28556; H01L 21/28568; H01L 29/401

(57) ABSTRACT

A semiconductor memory device includes a stacked body in which electrode films and insulating films are stacked alternately along a first direction, a semiconductor member extending in the first direction, and a charge storage member provided between the semiconductor member and the electrode film. The electrode film includes a first conductive layer and a second conductive layer. The first conductive layer is provided on an upper surface of the insulating film and on a lower surface of the insulating film. The second conductive layer is provided between the first conductive layer in a first portion of the electrode film. Thickness of the first conductive layer in the first portion is thinner than thickness of the first conductive layer in a second portion of the electrode film. The second portion is placed between the first portion and the semiconductor member.

### CROSS-REFERENCE TO RELATED APPLICATIONS

This application is based upon and claims the benefit of priority from Japanese Patent Application No.2017-059927, filed on Mar. 24, 2017; the entire contents of which are incorporated herein by reference.

### FIELD

Embodiments relate to a semiconductor memory device and a method for manufacturing the same.

### BACKGROUND

In recent years, there has been proposed a stacked-type semiconductor memory device in which memory cells are integrated three-dimensionally. Such a stacked-type semiconductor memory device is provided with a stacked body in which electrode films and insulating films are alternately stacked on a semiconductor substrate. Semiconductor pillars are provided through the stacked body. A memory cell transistor is formed for each crossing portion of the electrode film and the semiconductor pillar. A challenge for the stacked-type semiconductor memory device is to ensure reliability.

### BRIEF DESCRIPTION OF THE DRAWINGS

FIG. 1 is a perspective view showing a semiconductor memory device according to a first embodiment;

FIG. 2 is a plan view showing the semiconductor memory device according to the first embodiment;

FIG. 3 is a sectional view taken along line A-A′ shown in FIG. 2;

FIG. 4 is a sectional view showing a neighborhood of a silicon pillar of the semiconductor memory device according to the first embodiment;

FIGS. 5A to 5C, 6A to 6C, 7A to 7C are sectional views showing a method for manufacturing the semiconductor memory device according to the first embodiment;

FIG. 8 is a sectional view showing a semiconductor memory device according to a second embodiment; and

FIGS. 9A to 9C and 10 are sectional views showing a method for manufacturing the semiconductor memory device according to the second embodiment.

### DETAILED DESCRIPTION

In general, according to one embodiment, a semiconductor memory device includes a stacked body in which electrode films and insulating films are stacked alternately along a first direction, a semiconductor member extending in the first direction, and a charge storage member provided between the semiconductor member and the electrode film. The electrode film includes a first conductive layer and a second conductive layer. The first conductive layer is provided on an upper surface of the insulating film and on a lower surface of the insulating film. The second conductive layer is provided between the first conductive layer in a first portion of the electrode film. The second conductive layer is formed from a material different from that of the first conductive layer. Thickness of the first conductive layer in the first portion is thinner than thickness of the first conductive layer in a second portion of the electrode film. The second portion is placed between the first portion and the semiconductor member.

In general, according to other embodiment, a method for manufacturing a semiconductor memory device includes forming a slit in a stacked body. The stacked body has insulating films and first films stacked alternately along a first direction, a semiconductor member extending in the first direction, and a charge storage member provided between the semiconductor member and the first film. The slit extends in a second direction crossing the first direction. The method includes forming a space between the insulating films by removing the first film through the slit. The method includes forming a third conductive layer on an inner surface of the space through the slit. The method includes removing a portion of the third conductive layer through the slit. The portion is placed in a first portion of the space on the slit side. The method includes forming a fourth conductive layer thinner than the third conductive layer through the slit on the inner surface of the space in the first portion. The method includes forming a second conductive layer in the first portion.

### First Embodiment

A first embodiment is now described.

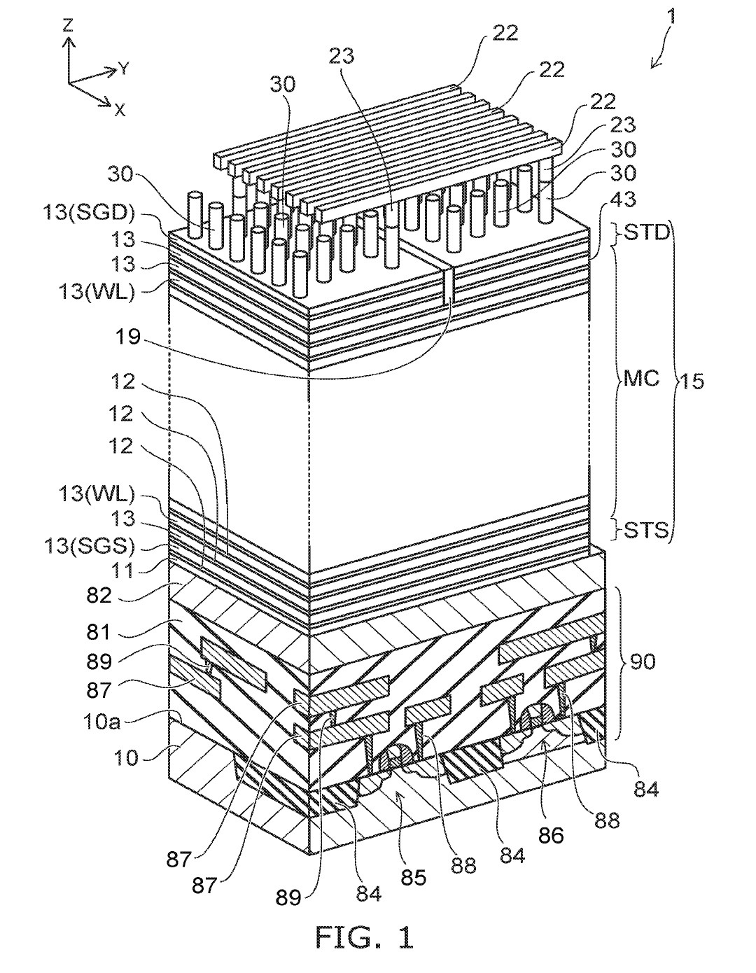

FIG. 1 is a perspective view showing a semiconductor memory device according to the embodiment.

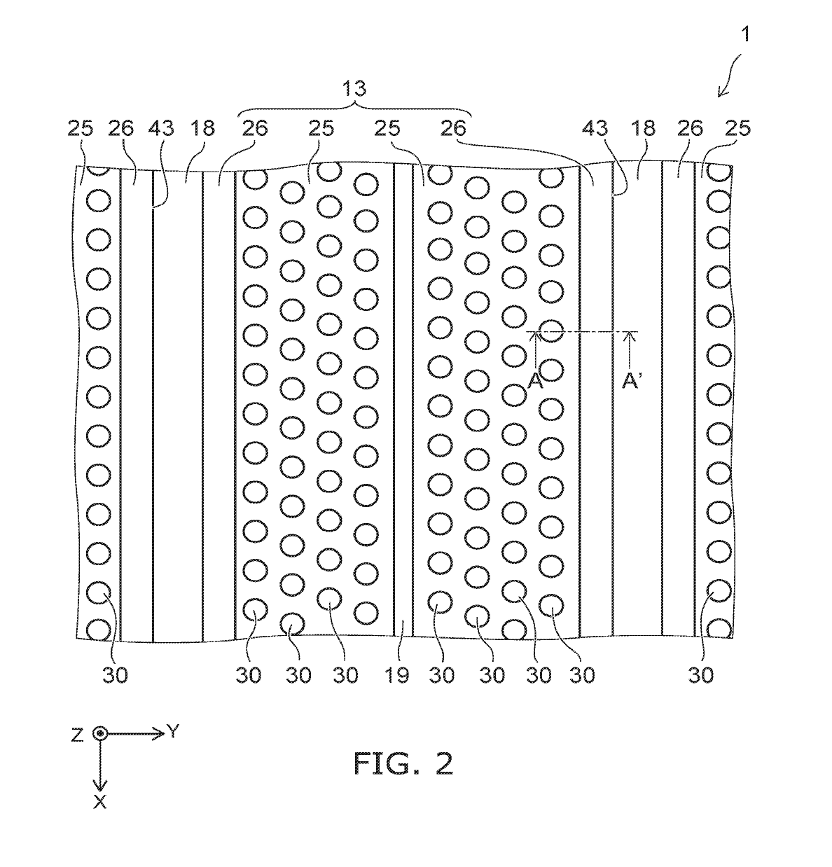

FIG. 2 is a plan view showing the semiconductor memory device according to the embodiment.

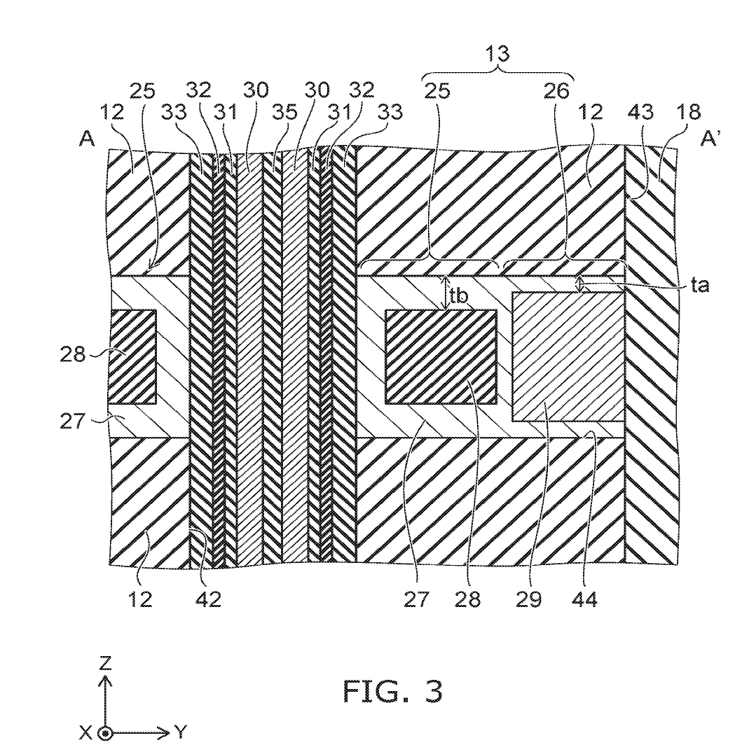

FIG. 3 is a sectional view taken along line A-A′ shown in FIG. 2.

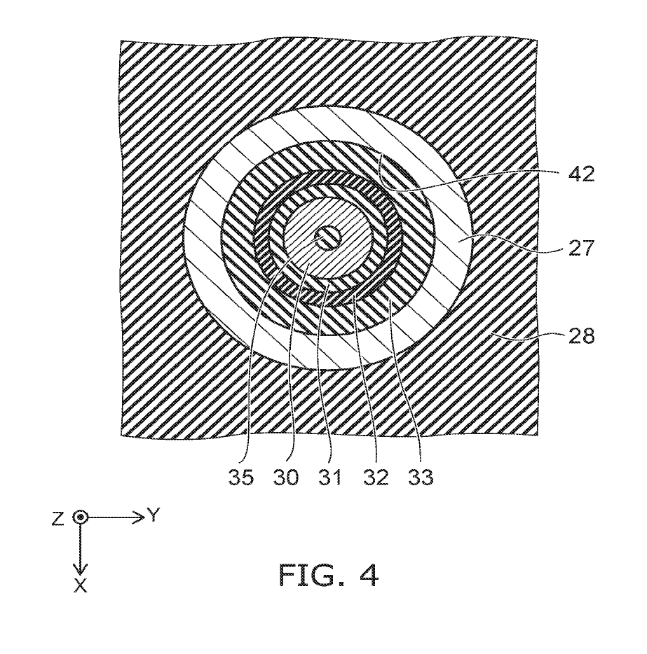

FIG. 4 is a sectional view showing the neighborhood of a silicon pillar of the semiconductor memory device according to the embodiment.

The drawings are schematic, and are emphasized and omitted as appropriate.

As shown in FIGS. 1 and 2, the semiconductor memory device 1 according to the embodiment is provided with a silicon substrate 10. The silicon substrate 10 is formed from e.g. a monocrystal of silicon (Si). An interlayer insulating film 81 is provided on the silicon substrate 10. The interlayer insulating film 81 is formed from e.g. silicon oxide (SiO). A source electrode film 82 is provided on the interlayer insulating film 81. The source electrode film 82 is formed from e.g. impurity-doped polysilicon.

In the following, in this specification, an XYZ orthogonal coordinate system is adopted for convenience of description. Two directions parallel to the upper surface 10a of the silicon substrate 10 and orthogonal to each other are referred to as “X-direction” and “Y-direction”. The direction perpendicular to the upper surface 10a of the silicon substrate 10 is referred to as “Z-direction”. In the Z-direction, the direction from the silicon substrate 10 toward the source electrode film 82 is also referred to as “upper”, and the opposite direction is also referred to as “lower”. However, these expressions are also used for convenience, and irrelevant to the direction of gravity.

In this specification, the “silicon substrate” refers to a substrate composed primarily of silicon (Si). The same also applies to the other components. That is, the component with the designation including a material name is composed primarily of that material. Furthermore, silicon is generally a semiconductor material. Thus, unless otherwise specified, the silicon substrate is a semiconductor substrate. The same also applies to the other components. That is, unless otherwise specified, the characteristics of the component reflect the characteristics of its main ingredient.

A cell underside circuit 90 is formed in an upper portion of the silicon substrate 10 and the interlayer insulating film 81. The cell underside circuit 90 is part of a driving circuit for performing writing, reading, and erasing of data on the memory cell transistor MC described later. The cell underside circuit 90 includes e.g. a sense amplifier. For instance, the upper portion of the silicon substrate 10 is partitioned into a plurality of active areas by STI (shallow trench isolation) 84. An n-type MOSFET (metal-oxide-semiconductor field-effect transistor) 85 is formed in one active area. A p-type MOSFET 86 is formed in another active area.

Interconnects 87 are provided in a plurality of stages in the interlayer insulating film 81. A contact 88 for connecting the interconnect 87 to the silicon substrate 10, and a via 89 for connecting the interconnects 87 to each other are also provided. In FIG. 1, the elements such as the n-type MOSFET 85, the p-type MOSFET 86, the interconnect 87 are depicted schematically, and are not necessarily consistent with the size and placement of actual elements.

A silicon oxide film 11 is provided on the source electrode film 82. Silicon oxide films 12 and electrode films 13 are stacked alternately along the Z-direction on the silicon oxide film 11. A stacked body 15 is formed from a plurality of silicon oxide films 12 and a plurality of electrode films 13 stacked alternately.

A slit 43 extending in the X-direction is formed in the stacked body 15. The slit 43 divides the stacked body 15 in the Y-direction. In the stacked body 15 divided by the slit 43, each electrode film 13 extends in the X-direction. That is, the X-direction length of the electrode film 13 is longer than the Z-direction length (thickness) of the electrode film 13 and the Y-direction length (width) of the electrode film 13. A silicon oxide plate 18 is provided in the slit 43. A silicon oxide member 19 extending in the X-direction is provided in an upper part of the Y-direction central portion of the stacked body 15 divided by the slit 43.

A silicon pillar 30 extending in the Z-direction and penetrating through the stacked body 15 is provided in the stacked body 15. The silicon pillar 30 is made of polysilicon. The silicon pillar 30 is shaped like e.g. a circular cylinder occluded at the lower end. The lower end of the silicon pillar 30 is connected to the source electrode film 82. The upper end of the silicon pillar 30 is exposed at the upper surface of the stacked body 15. The silicon pillars 30 are arranged periodically along a plurality of rows, such as eight rows, extending in the X-direction. The eight rows of silicon pillars 30 are placed on both Y-direction sides of the silicon oxide member 19, four rows on each side. As viewed in the Z-direction, the silicon pillars 30 are arranged in a staggered arrangement. The placement of the silicon pillars 30 are not limited to eight rows, but may be e.g. four rows.

A plurality of bit lines 22 extending in the Y-direction are provided on the stacked body 15. The bit line 22 is connected to the upper end of the silicon pillar 30 through a plug 23. Thus, the silicon pillar 30 is connected between the bit line 22 and the source electrode film 82.

In the stacked body 15, one or more stages of electrode films 13 from the top function as upper select gate lines SGD. An upper select gate transistor STD is configured for each crossing portion of the upper select gate line SGD and the silicon pillar 30. The silicon oxide member 19 is placed between the upper select gate lines SGD. One or more stages of electrode films 13 from the bottom function as lower select gate lines SGS. A lower select gate transistor STS is configured for each crossing portion of the lower select gate line SGS and the silicon pillar 30.

The electrode films 13 other than the lower select gate lines SGS and the upper select gate lines SGD function as word lines WL. A memory cell transistor MC is configured for each crossing portion of the word line WL and the silicon pillar 30. Thus, a plurality of memory cell transistors MC are connected in series along each silicon pillar 30. The lower select gate transistor STS and the upper select gate transistor STD are connected to both ends of the silicon pillar 30. Accordingly, a NAND string is formed.

As shown in FIGS. 3 and 4, a core member 35 made of e.g. silicon oxide is provided in the silicon pillar 30. Between the silicon pillar 30 and the electrode film 13, a tunnel insulating film 31, a charge storage film 32, and a block insulating film 33 are provided in this order from the silicon pillar 30 toward the electrode film 13. The tunnel insulating film 31, the charge storage film 32, and the block insulating film 33 are shaped like a circular cylinder surrounding the silicon pillar 30. The core member 35, the tunnel insulating film 31, the charge storage film 32, and the block insulating film 33 are omitted in FIGS. 1 and 2.

The tunnel insulating film 31 is a film that is normally insulating, but passes a tunnel current under application of a prescribed voltage within the range of the driving voltage of the semiconductor memory device 1. For instance, the tunnel insulating film 31 is formed from silicon oxide (SiO). The charge storage film 32 is a film capable of storing charge. For instance, the charge storage film 32 is formed from silicon nitride (SiN). The block insulating film 33 is a film passing substantially no current even under application of voltage within the range of the driving voltage of the semiconductor memory device 1. For instance, the block insulating film 33 is a stacked film of a silicon oxide layer and a high-dielectric layer.

As shown in FIGS. 2 and 3, the structure of the electrode film 13 is different between the central portion 25 and the end portion 26 of the electrode film 13. In the portion of the electrode film 13 divided by the slit 43, the central portion 25 is placed in the Y-direction central part, and the end portions 26 are placed on both Y-direction end parts. The central portion 25 and the end portion 26 both extend in the X-direction. As viewed in the Z-direction, the boundary between the central portion 25 and the end portion 26 is shaped like a straight line extending in the X-direction. The silicon pillar 30 penetrates through the central portion 25.

The electrode film 13 is provided with a barrier metal layer 27, an insulating layer 28, and a metal layer 29. The barrier metal layer 27 is formed from e.g. metal nitride such as titanium nitride (TiN) and tungsten nitride (WN). The barrier metal layer 27 is provided on the upper surface and the lower surface of the silicon oxide film 12 and on the side surface of the block insulating film 33. The insulating layer 28 is made of e.g. silicon oxide. The insulating layer 28 is placed between the barrier metal layers 27 in the central portion 25 of the electrode film 13. The metal layer 29 is made of e.g. metal such as tungsten (W). The metal layer 29 is placed between the barrier metal layers 27 in the end portion 26 of the electrode film 13. For instance, the resistivity of the metal layer 29 is lower than the resistivity of the barrier metal layer 27. The barrier metal layer 27 is placed also between the insulating layer 28 and the metal layer 29.

In the Z-direction, the thickness to of the barrier metal layer 27 in the end portion 26 is thinner than the thickness tb of the barrier metal layer 27 in the central portion 25, i.e., ta<tb. The thickness ta is e.g. half or less of the thickness tb. On the other hand, the thickness of the electrode film 13 is generally uniform. That is, in the Z-direction, the thickness of the central portion 25 and the thickness of the end portion 26 are generally equal. Thus, the metal layer 29 is thicker than the insulating layer 28.

Next, a method for manufacturing the semiconductor memory device according to the embodiment is described.

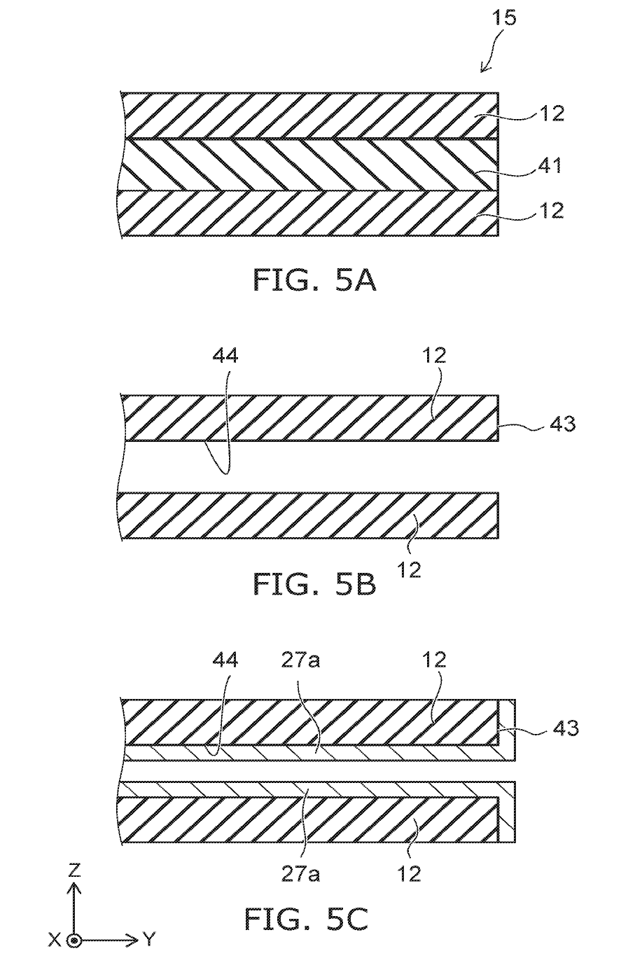

FIGS. 5A to 5C, 6A to 6C, 7A to 7C are sectional views showing a method for manufacturing the semiconductor memory device according to the embodiment.

First, as shown in FIG. 1, an interlayer insulating film 81 and a cell underside circuit 90 are formed on the silicon substrate 10. Next, a source electrode film 82 is formed, and a silicon oxide film 11 is formed on the source electrode film 82.

Next, as shown in FIG. 5A, silicon oxide films 12 and silicon nitride films 41 are alternately stacked to form a stacked body 15.

Next, as shown in FIGS. 3 and 4, a memory hole 42 extending in the Z-direction is formed in the stacked body 15. A block insulating film 33, a charge storage film 32, a tunnel insulating film 31, a silicon pillar 30, and a core member 35 are formed in this order on the inner surface of the memory hole 42. Next, a silicon oxide member 19 extending in the X-direction is formed in an upper part of the stacked body 15. The silicon oxide member 19 divides one or more silicon nitride films 41 from the top.

Next, as shown in FIG. 5B, a slit 43 extending in the X-direction is formed in the stacked body 15. The slit 43 is caused to penetrate through the stacked body 15 and the silicon oxide film 11 to the source electrode film 82. The slit 43 only needs to reach the lowermost silicon nitride film 41 of the stacked body 15.

Next, the silicon nitride films 41 are removed by e.g. wet etching through the slit 43. Thus, a space 44 is formed after the removal of the silicon nitride films 41. In the Z-direction, the space 44 is located between the silicon oxide films 12. At this time, the block insulating film 33 is not removed. Thus, the block insulating film 33, and the charge storage film 32, the tunnel insulating film 31, the silicon pillar 30, and the core member 35 surrounded with the block insulating film 33 remain and serve as a strut for supporting the stacked body 15.

Next, as shown in FIG. 5C, metal nitride such as titanium nitride (TiN) or tungsten nitride (WN) is deposited by e.g. the CVD (chemical vapor deposition) method. Thus, a barrier metal layer 27a is formed on the inner surface of the slit 43 and on the inner surface of the space 44, i.e., on the upper surface and the lower surface of the silicon oxide film 12 and on the side surface of the block insulating film 33.

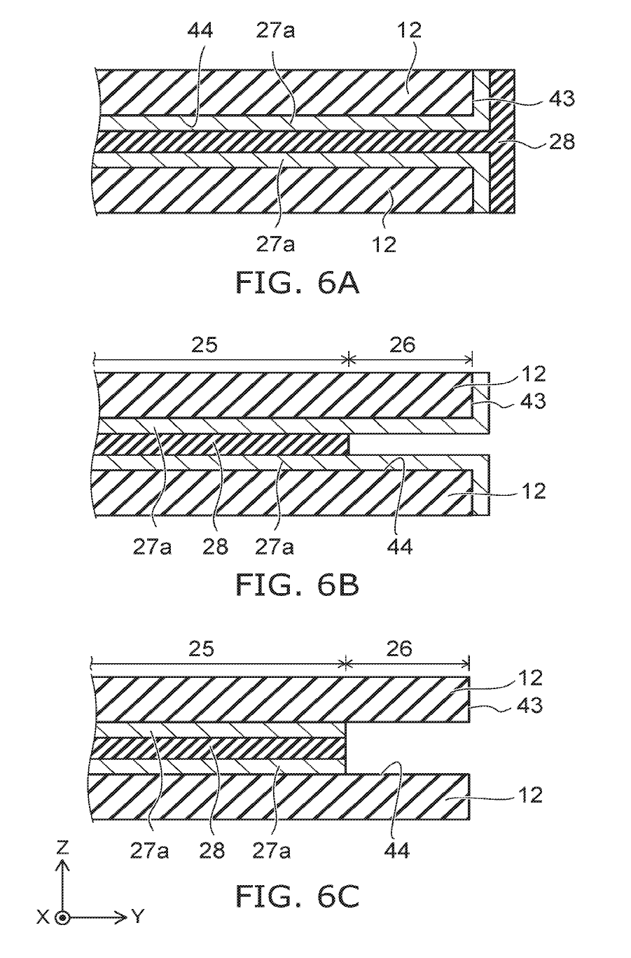

As shown in FIG. 6A, silicon oxide is deposited by e.g. the CVD method. Thus, an insulating layer 28 is formed in the slit 43 and in the space 44.

Next, as shown in FIG. 6B, by isotropic etching, the insulating layer 28 is removed from inside the slit 43 and the portion of the space 44 located on the slit 43 side. As a result, the insulating layer 28 is removed from the portion (end portion 26) of the space 44 on the slit 43 side. At this time, the insulating layer 28 remains in the portion (central portion 25) of the space 44 spaced from the slit 43.

Next, as shown in FIG. 6C, the remaining insulating layer 28 is used as a mask to perform isotropic etching on the barrier metal layer 27a. Thus, the barrier metal layer 27a is removed from the side surface of the slit 43 and inside the end portion 26 of the space 44. On the other hand, the barrier metal layer 27a remains in the central portion 25 of the space 44.

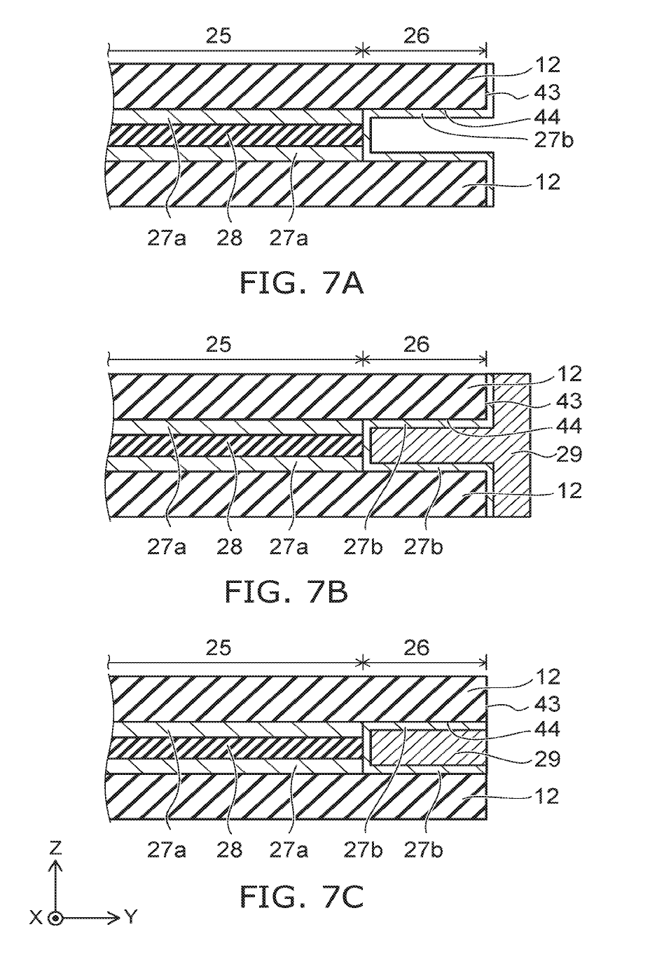

Next, as shown in FIG. 7A, metal nitride such as titanium nitride or tungsten nitride is deposited by e.g. the CVD method. Thus, a barrier metal layer 27b is formed on the inner surface of the slit 43 and on the inner surface of the end portion 26 of the space 44. The barrier metal layer 27b is formed also on the exposed surface of the insulating layer 28. The thickness of the barrier metal layer 27b is made thinner than, e.g., half or less of the thickness of the barrier metal layer 27a. For instance, the thickness of the barrier metal layer 27b is set to 2-3 nm (nanometers).

Next, as shown in FIG. 7B, tungsten (W) is deposited by e.g. the CVD method using tungsten hexafluoride (WF₆) as a raw material gas. The deposition amount of tungsten is set to an amount such that the space 44 is completely filled and the slit 43 is not completely filled. As a result, a metal layer 29 is formed in the end portion 26 of the space 44 and on the inner surface of the slit 43.

Next, as shown in FIG. 7C, the metal layer 29 and the barrier metal layer 27b are removed from the inner surface of the slit 43 by etching. At this time, the metal layer 29 and the barrier metal layer 27b are left in the end portion 26 of the space 44. The barrier metal layers 27a and 27b are integrated into a barrier metal layer 27. Thus, an electrode film 13 composed of the barrier metal layer 27, the insulating layer 28, and the metal layer 29 is formed in the space 44.

Next, as shown in FIGS. 1 to 4, silicon oxide is buried in the slit 43 to form a silicon oxide plate 18. Next, a plug 23 and a bit line 22 are formed on the stacked body 15 and connected to the silicon pillar 30. Thus, the semiconductor memory device 1 according to the embodiment is manufactured.

Next, the effect of the embodiment is described.

In the semiconductor memory device 1 according to the embodiment, as shown in FIG. 3, the metal layer 29 made of tungsten is provided only in the end portion 26 of the electrode film 13. This can reduce stress due to tungsten compared with the case of providing the metal layer 29 entirely in the electrode film 13 and suppress the deformation of the stacked body 15. Thus, the semiconductor memory device 1 has high reliability.

The block insulating film 33 is spaced from the metal layer 29 by the barrier metal layer 27 and the insulating layer 28. Thus, when depositing tungsten in the step shown in FIG. 7B, the block insulating film 33 is not exposed to fluorine contained in the raw material gas of the CVD method. Fluorine in the raw material gas filled in the space 44 needs to diffuse through the insulating layer 28 and the barrier metal layer 27 to reach the block insulating film 33. This can suppress degradation of the memory cell transistor MC caused by intrusion of fluorine into the portion surrounded with the block insulating film 33. This can also improve the reliability of the semiconductor memory device 1.

Furthermore, in the embodiment, as shown in FIG. 3, the thickness to of the barrier metal layer 27 in the end portion 26 of the electrode film 13 is thinner than the thickness tb of the barrier metal layer 27 in the central portion 25. Thus, conductivity is ensured by thickly forming the barrier metal layer 27 in the central portion 25, and conductivity can be improved by thickly forming the metal layer 29 in the end portion 26. The metal such as tungsten forming the metal layer 29 has higher conductivity than the metal nitride forming the barrier metal layer 27. The end portion 26 extends in the X-direction without being obstructed by e.g. the block insulating film 33. Thus, the metal layer 29 has significant influence on the conductivity of the entire electrode film 13. Accordingly, the conductivity of the electrode film 13 can be effectively improved by thickly forming the metal layer 29. This can improve the operating speed of the semiconductor memory device 1.

### Second Embodiment

Next, a second embodiment is described.

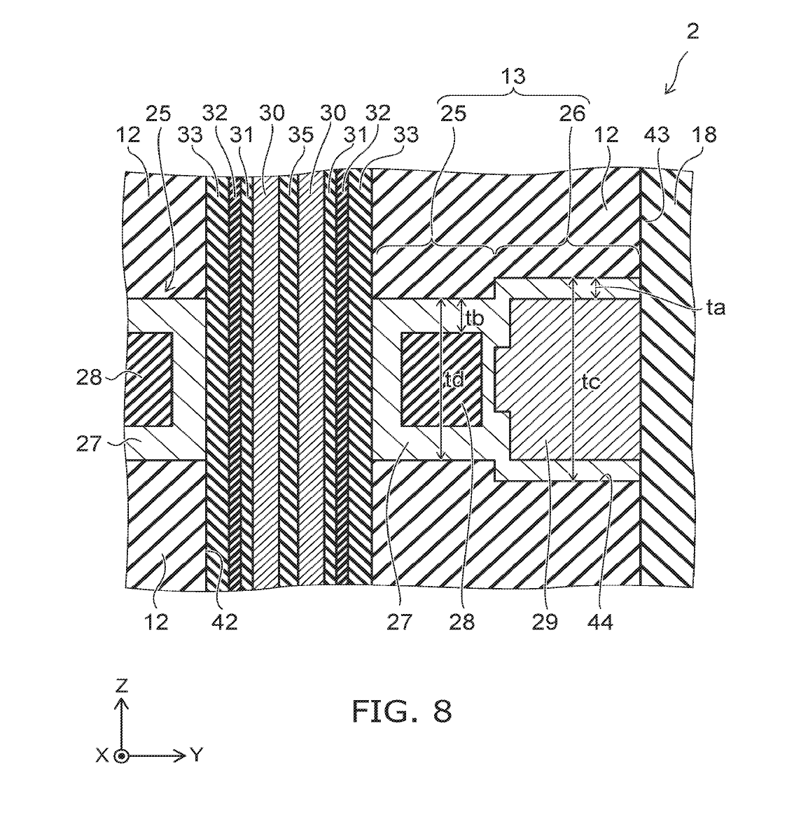

FIG. 8 is a sectional view showing a semiconductor memory device according to the embodiment.

The region shown in FIG. 8 corresponds to the region shown in FIG. 3 in the first embodiment.

As shown in FIG. 8, the semiconductor memory device 2 according to the embodiment is different from the semiconductor memory device 1 (see FIGS. 1 to 4) according to the above first embodiment in that the Z-direction thickness tc of the end portion 26 of the electrode film 13 is thicker than the Z-direction thickness td of the central portion 25, i.e., tc>td. As in the first embodiment, the thickness ta of the barrier metal layer 27 placed in the end portion 26 is thinner than the thickness tb of the barrier metal layer 27 placed in the central portion 25, i.e., ta<tb. Thus, the metal layer 29 is thicker than in the first embodiment. In other words, the Z-direction thickness of the portion of the insulating film 12 sandwiched between the end portions 26 of the electrode film 13 is thinner than the thickness of the portion of the insulating film 12 sandwiched between the central portions 25 of the electrode film 13.

Next, a method for manufacturing the semiconductor memory device according to the embodiment is described.

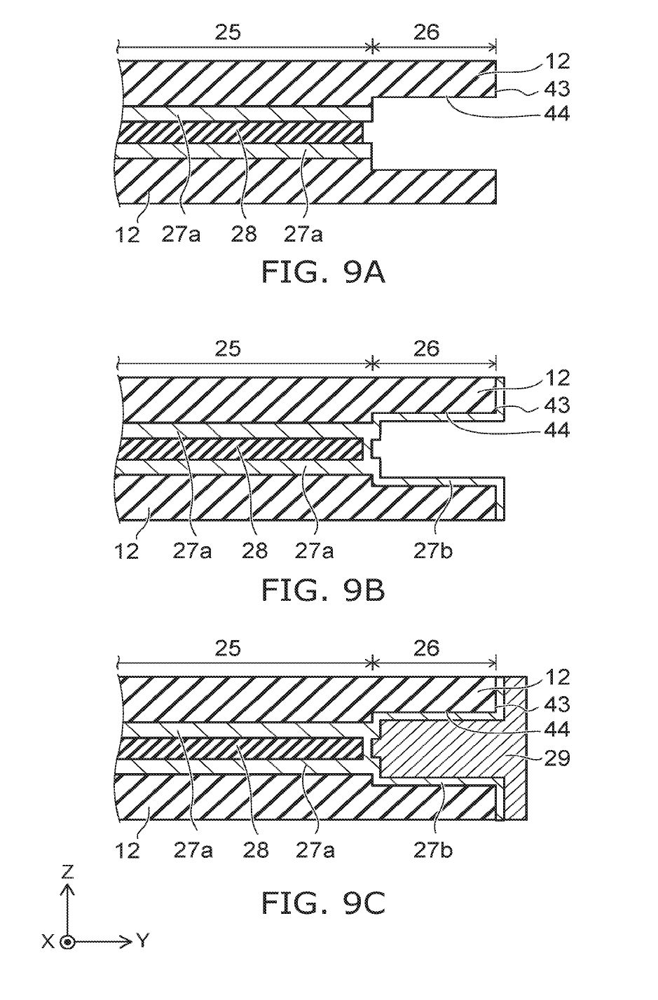

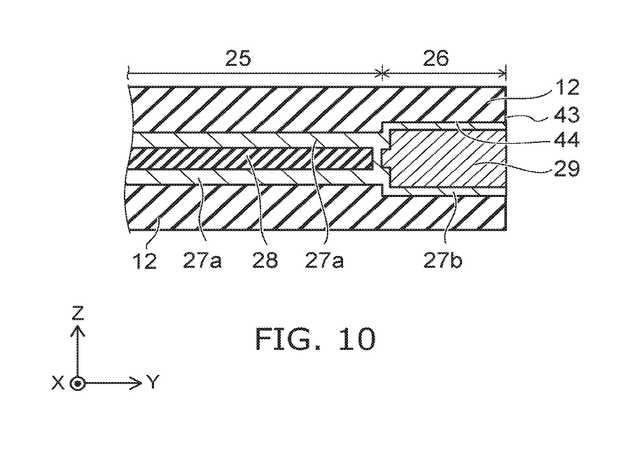

FIGS. 9A to 9C and 10 are sectional views showing a method for manufacturing the semiconductor memory device according to the embodiment.

First, the steps of FIGS. 5A to 5C, 6A to 6C are performed by a method similar to the above first embodiment.

Next, as shown in FIG. 9A, isotropic etching is performed on silicon oxide through the slit 43. This recesses the region of the inner surface of the space 44 not covered with the barrier metal layer 27a and expands the space 44 in the Z-direction. At this time, the exposed surface of the insulating layer 28 is also recessed.

Next, as shown in FIG. 9B, titanium nitride is deposited by e.g. the CVD method. Thus, a barrier metal layer 27b is formed on the inner surface of the slit 43 and on the inner surface of the end portion 26 of the space 44. The barrier metal layer 27b is made thinner than, e.g., half or less of the barrier metal layer 27a.

Next, as shown in FIG. 9C, tungsten is deposited by e.g. the CVD method using tungsten hexafluoride (WF₆) as a raw material gas. Thus, a metal layer 29 is formed in the end portion 26 of the space 44 and on the inner surface of the slit 43.

Next, as shown in FIG. 10, by etching, the metal layer 29 and the barrier metal layer 27b are removed from the inner surface of the slit 43, and left in the end portion 26 of the space 44. Thus, an electrode film 13 is formed in the space 44. The subsequent manufacturing method is similar to the above first embodiment. Thus, the semiconductor memory device 2 according to the embodiment is manufactured.

Next, the effect of the embodiment is described.

In the embodiment, in the step shown in FIG. 9A, the space 44 is expanded in the Z-direction. Thus, as shown in FIG. 8, in the manufactured semiconductor memory device 2, the Z-direction thickness tc of the end portion 26 of the electrode film 13 is thicker than the Z-direction thickness td of the central portion 25. Accordingly, the metal layer 29 can be made thicker than in the above first embodiment. This can further improve the conductivity of the electrode film 13.

The configuration, manufacturing method, and effect of the embodiment other than the foregoing are similar to those of the above first embodiment.

The embodiments described above can realize a semiconductor memory device having high reliability and a manufacturing method thereof.

In the example shown in the above first and second embodiments, the barrier metal layer 27 is formed from metal nitride such as titanium nitride, and the metal layer 29 is formed from metal such as tungsten. However, the embodiments are not limited thereto, but an arbitrary conductive material can be used.

In the example shown in the above first and second embodiments, the insulating layer 28 is formed from silicon oxide. However, the embodiments are not limited thereto, but an arbitrary insulating material can be used. A conductive layer may be provided instead of the insulating layer 28 as long as there is no trouble such as shape failure due to stress and quality degradation due to process gas. Furthermore, an air gap may be formed instead of providing the insulating layer 28.

Furthermore, in the example shown in the above first and second embodiments, the cell underside circuit 90 and the source electrode film 82 are provided between the silicon substrate 10 and the stacked body 15, and the lower end of the silicon pillar 30 is connected to the source electrode film 82. However, the embodiments are not limited thereto. For instance, the cell underside circuit 90 and the source electrode film 82 may not be provided, and the lower end of the silicon pillar 30 may be connected to the silicon substrate 10. In this case, for instance, a conductive member for applying a source potential from the upper interconnect to the silicon substrate 10 may be provided in the silicon oxide plate 18.

Moreover, in the example shown in the above first and second embodiments, the insulating layer 28 is necessarily placed between the block insulating film 33 and the silicon oxide plate 18. However, the embodiments are not limited thereto. For instance, depending on the process condition, the diameter of the memory hole 42 may become larger and the width of the slit 43 may become wider toward the upper part of the stacked body 15. In this case, in the upper part of the stacked body 15, the distance between the memory hole 42 nearest to the slit 43 and the slit 43 becomes shorter. Thus, in the step shown in FIG. 6B, the insulating layer 28 may not remain between the block insulating film 33 nearest to the slit 43 and the slit 43. Even in this case, the block insulating film 33 is spaced from the raw material gas of the CVD method at least by the barrier metal layer 27. This can suppress damage to the memory cell transistor MC by fluorine.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which electrode films and insulating films are stacked alternately along a first direction;
a semiconductor member extending in the first direction; and
a charge storage member provided between the semiconductor member and the electrode film,
the electrode film including:
a first conductive layer provided on an upper surface of the insulating film and on a lower surface of the insulating film; and
a second conductive layer provided between the first conductive layer in a first portion of the electrode film and formed from a material different from that of the first conductive layer, and
thickness of the first conductive layer in the first portion being thinner than thickness of the first conductive layer in a second portion of the electrode film placed between the first portion and the semiconductor member.

2. The device according to claim 1, further comprising:
an insulating plate placed in a second direction crossing the first direction as viewed from the stacked body,
wherein the charge storage member, the second portion, the first portion, and the insulating plate are arranged in this order in the second direction.

3. The device according to claim 1, wherein thickness of the first portion in the first direction is thicker than thickness of the second portion in the first direction.

4. The device according to claim 1, wherein thickness in the first direction of a portion of the insulating film sandwiched between the first portions is thicker than thickness in the first direction of a portion of the insulating film sandwiched between the second portions.

5. The device according to claim 1, wherein the second conductive layer contains tungsten.

6. The device according to claim 1, further comprising:
a first insulating layer provided between the first conductive layers in the second portion.

7. A method for manufacturing a semiconductor memory device, comprising:
in a stacked body including insulating films and first films stacked alternately along a first direction, a semiconductor member extending in the first direction, and a charge storage member provided between the semiconductor member and the first film, forming a slit extending in a second direction crossing the first direction;
forming a space between the insulating films by removing the first film through the slit;
forming a third conductive layer on an inner surface of the space through the slit;
removing a portion of the third conductive layer through the slit, the portion being placed in a first portion of the space on the slit side;
forming a fourth conductive layer thinner than the third conductive layer through the slit on the inner surface of the space in the first portion; and
forming a second conductive layer in the first portion.

8. The method according to claim 7, further comprising:
forming a first insulating layer in a second portion of the space between the semiconductor member and the first portion after the forming a third conductive layer,
wherein the removing a portion of the third conductive layer includes performing etching using the first insulating layer as a mask.

9. The method according to claim 7, further comprising:
expanding the first portion of the space in the first direction by etching the insulating film through the slit after the removing a portion of the third conductive layer and before the forming a fourth conductive layer.
